(19) United States
(12) Patent Application Publication
(10) Pub. No.: US 2024/0178194 A1
(43) Pub. Date: May 30, 2024

(54) SEMICONDUCTOR MODULE

(71) Applicant: DENSO CORPORATION, Kariya-city (JP)

(72) Inventor: Shingo IWASAKI, Kariya-city (JP)

(73) Assignee: DENSO CORPORATION, Kariya-city (JP)

(21) Appl. No.: 18/433,910

(22) Filed: Feb. 6, 2024

Related U.S. Application Data
(63) Continuation of application No. PCT/JP2022/027868, filed on Jul. 15, 2022.

(30) Foreign Application Priority Data
Aug. 6, 2021 (JP) 2021-130016

(51) Int. Cl. H01L 25/07; H01L 23/00; H02M 7/00; H02M 7/5387

(52) U.S. Cl. CPC H01L 25/072; H01L 24/32; H01L 24/40; H01L 24/73; H02M 7/003; H02M 7/5387; H01L 2224/32245; H01L 2224/40137; H01L 2224/73263; H01L 2924/13055

(57) ABSTRACT

A semiconductor module includes a circuit board, semiconductor switching elements for an inverter circuit connected to the circuit board, bus bars, and a mold integrally sealing the circuit board, the semiconductor switching elements, and the bus bars. The switching elements are disposed in a plane direction of the circuit board. The bus bars include a first bus bar serially connecting the switching elements in each leg of the inverter circuit to each other and a second bus bar connected to a high potential side or a low potential side of the leg and disposed between the first bus bar and the circuit board. The first bus bar and the second bus bar at least partly overlap. The direction of a current flowing through the first bus bar is opposite to the direction of a current flowing through the second bus bar.

### CROSS-REFERENCE OF RELATED APPLICATIONS

This application is the U.S. bypass application of International Application No. PCT/JP2022/027868 filed on Jul. 15, 2022, which designated the U.S. and claims priority to Japanese Patent Application No. 2021-130016 filed on Aug. 6, 2021 the contents of which are incorporated herein by reference.

### BACKGROUND

### Technical Field

The present disclosure relates to a semiconductor module that includes a plurality of semiconductor elements.

### Description of the Related Art

A semiconductor module integrating a plurality of semiconductor elements is known. As an example, a semiconductor module is disclosed in which an insulating substrate, a printed circuit board, and a plurality of semiconductor elements are integrally sealed in sealing resin. The plurality of semiconductor elements is disposed on the upper surface side of the insulating substrate and on the lower surface side of the printed circuit board. The plurality of semiconductor elements is bonded to the upper surface of an electrically conductive layer disposed on the upper surface of the insulating substrate via a solder layer and to the lower surface of an electrically conductive layer disposed on the lower surface of the printed circuit board via a solder layer. Through holes vertically extend through the printed circuit board, and signal electrodes of the plurality of semiconductor elements are electrically connected to the printed circuit board by electrically conductive members disposed in the through holes.

### SUMMARY

The present disclosure includes a circuit board, a plurality of semiconductor switching elements applied to an inverter circuit connected to the circuit board, a plurality of bus bars, and a mold that integrally seals the circuit board, the plurality of semiconductor switching elements, and the plurality of bus bars. In this semiconductor module, the plurality of semiconductor switching elements is disposed in a plane direction of the circuit board. The plurality of bus bars includes a first bus bar that serially connects the plurality of semiconductor switching elements contained in each leg of the inverter circuit and a second bus bar that is connected to a high potential side or a low potential side of the leg and disposed between the first bus bar and the circuit board. When the circuit board is seen in the plan view direction, the first bus bar and the second bus bar at least partly overlap each other, and the direction of a current flowing through the first bus bar is opposite to the direction of a current flowing through the second bus bar.

### BRIEF DESCRIPTION OF THE DRAWINGS

The above and other objects, features, and advantages of the present disclosure will become clearer from the following detailed description with reference to the accompanying drawings. The drawings are as follows.

FIG. 1 is a perspective view illustrating an appearance of a semiconductor module according to an embodiment;

FIG. 2 is a diagram of an inverter circuit integrated in the semiconductor module illustrated in FIG. 1;

FIG. 3 is a plan view illustrating a state in which a mold is removed from the semiconductor module illustrated in FIG. 1;

FIG. 4 is a perspective view illustrating a state in which a mold is removed from the semiconductor module illustrated in FIG. 1;

FIG. 5 is a cross-sectional view along line V-V of FIG. 4;

FIG. 6 is a cross-sectional view along line VI-VI of FIG. 4;

FIG. 7 is a cross-sectional view along line VII-VII of FIG. 4;

FIG. 8 is a plan view illustrating a state in which a circuit board is removed from the state illustrated in FIG. 3;

FIG. 9 is a perspective view illustrating a state in which a circuit board is further removed from the state illustrated in FIG. 4,

FIG. 10 is a cross-sectional view along line X-X of FIG. 8;

FIG. 11 is a plan view illustrating a state in which a second bus bar is further removed from the state illustrated in FIG. 8;

FIG. 12 is a perspective view illustrating a state in which a second bus bar is further removed from the state illustrated in FIG. 9;

FIG. 13 is a cross-sectional view illustrating a state in which a second bus bar is further removed from the state illustrated in FIG. 10;

FIG. 14 is a diagram schematically illustrating a cross section of the semiconductor module;

FIGS. 15A and 15B are diagrams each illustrating a current flowing through a first bus bar and a current flowing through a second bus bar;

FIG. 16 is a diagram illustrating a state of wirelessly communicating with an external circuit board by a wireless communication circuit provided to a circuit board;

FIG. 17 is a view illustrating a state of being connected with an external circuit board by external terminals provided to a circuit board; and

FIG. 18 is a view illustrating a semiconductor module that includes low shrinkage layers in a mold.

### DETAILED DESCRIPTION OF THE PREFERRED EMBODIMENTS

A patent literature JP 2019-153607A discloses a semiconductor module in which an insulating substrate, a printed circuit board, and a plurality of semiconductor elements are integrally sealed in sealing resin. The plurality of semiconductor elements is disposed on the upper surface side of the insulating substrate and on the lower surface side of the printed circuit board. The plurality of semiconductor elements is bonded to the upper surface of an electrically conductive layer disposed on the upper surface of the insulating substrate via a solder layer and to the lower surface of an electrically conductive layer disposed on the lower surface of the printed circuit board via a solder layer. Through holes vertically extend through the printed circuit board, and signal electrodes of the plurality of semiconductor elements are electrically connected to the printed circuit board by electrically conductive members disposed in the through holes.

In the above-described patent literature, a plurality of electrically conductive layers having different potentials is adjacently disposed on the same plane between the printed circuit board and the plurality of semiconductor elements. Therefore, there is the concern that in response to a current or a potential sharply changing in the semiconductor module, a magnetic noise or an electrostatic noise may occur and cause malfunction of the printed circuit board.

With reference to the drawings, embodiments of the present disclosure will be described.

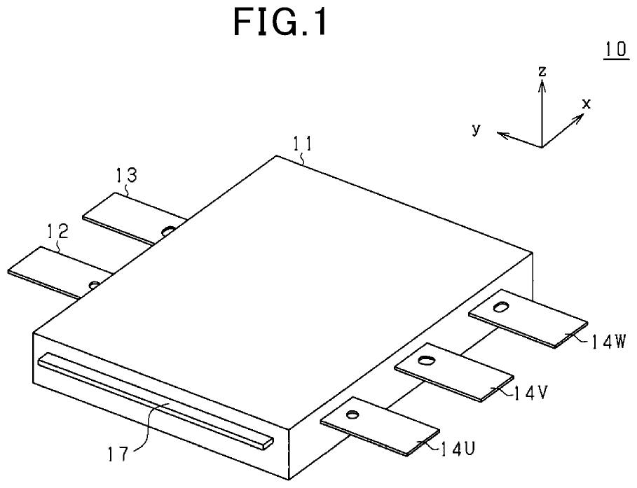

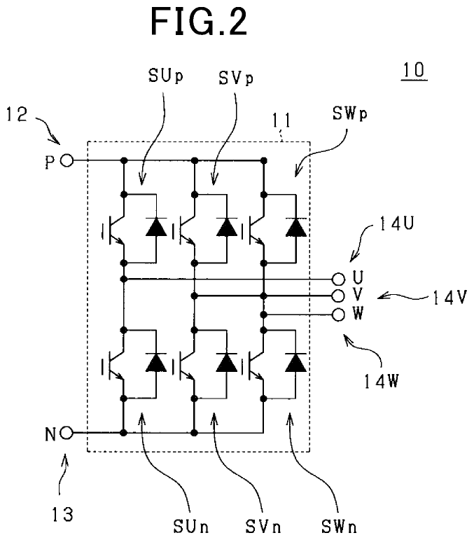

As illustrated in FIG. 1, in a semiconductor module 10, a circuit board 17 and six semiconductor switching elements are integrally sealed in a rein mold 11. The six semiconductor switching elements are n-channel RC-IGBTs having similar structures and sizes. In the semiconductor module 10, the six semiconductor switching elements constitute an inverter circuit as illustrated in FIG. 2.

The inverter circuit is a three-phase full bridge circuit which contains three legs each constituted by two serially-connected semiconductor switching elements. An upper-arm switch SUp and a lower-arm switch SUb connected to a U terminal 14U, an upper-arm switch SVp and a lower-arm switch SVn connected to a V terminal 14V, and an upper-arm switch SWp and a lower-arm switch SWn connected to a W terminal 14W are sealed in the mold 11. The high potential side of each leg is connected to a P terminal 12, and the low potential side is connected to an N terminal 13.

As illustrated in FIG. 1, the appearance is such that the P terminal 12, the N terminal 13, the U terminal 14U, the V terminal 14V, and the W terminal 14W, and the circuit board 17 partly project from the mold 11. Allowing the circuit board 17 to partly project from the mold 11 enables heat to be dissipated from the projecting portion. It is noted that in the drawings, the x direction and the y direction are directions parallel to the plane direction of the semiconductor module 10 and the circuit board 17, and the z direction is the thickness direction of the semiconductor module 10 and the circuit board 17. The P terminal 12 and the N terminal 13 are adjacent to each other in the x direction and project in the positive direction of y axis with respect to the mold 11. The positions in z direction of the P terminal 12 and the N terminal 13 are substantially the same. The U terminal 14U, the V terminal 14V, and the W terminal 14W project in the negative direction of x axis that is opposite to the P terminal 12 and the N terminal 13 with respect to the mold 11. The U terminal 14U, the V terminal 14V, and the W terminal 14W are adjacently disposed in this order from the negative direction side of x axis toward the positive direction side. The positions in the z direction of the U terminal 14U, the V terminal 14V, and the W terminal 14W are substantially the same.

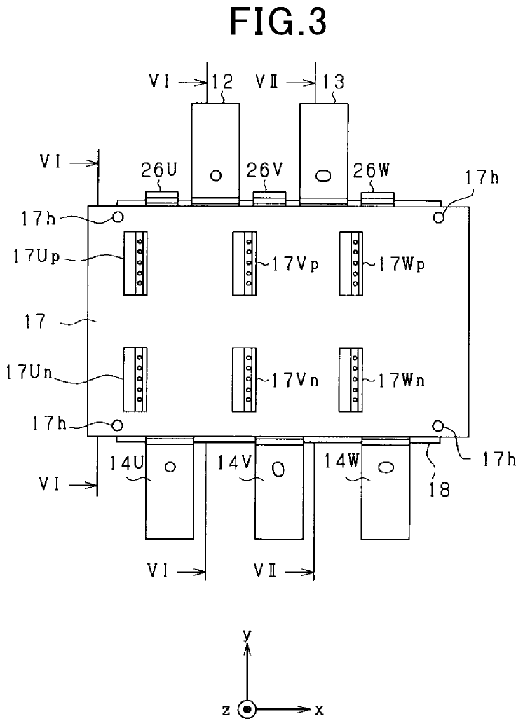

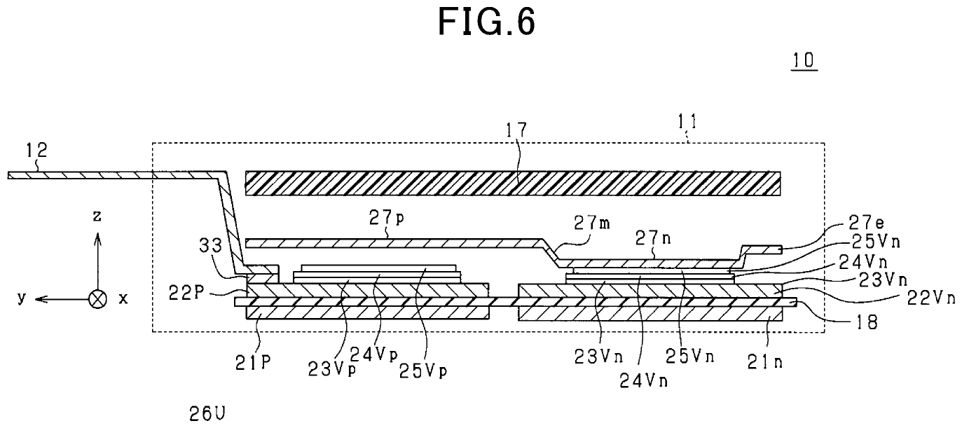

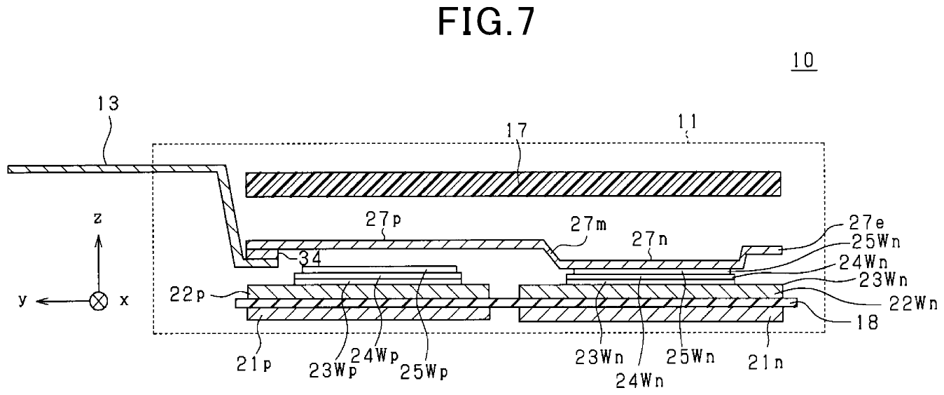

FIGS. 3 to 7 are each a view illustrating a state in which the mold 11 is removed from the semiconductor module 10 illustrated in FIG. 1. As illustrated in FIGS. 3 to 7, the semiconductor module 10 includes the circuit board 17, six semiconductor switching elements 24Up, 24Un, 24Vp, 24Vn, 24Wp, and 24Wn, and three first bus bars 26U, 26V, and 26W, which are integrally sealed in the mold 11. The semiconductor switching elements 24Up, 24Un, 24Vp, 24Vn, 24Wp, and 24Wn respectively correspond to the upper-arm switch SUp, the lower-arm switch SUb, the upper-arm switch SVp, the lower-arm switch SVn, the upper-arm switch SWp, and the lower-arm switch SWn illustrated in FIG. 2. Pairs of semiconductor switching elements 24Up and 24Un, 24Vp and 24Vn, and 24Wp and 24Wn contained in corresponding legs are each disposed in the y direction. The semiconductor switching elements 24Up, 24Vp, and 24Wp corresponding to the upper-arm switches are disposed in the positive direction side of y axis which is close to the P terminal 12 and the N terminal 13, and the semiconductor switching elements 24Un, 24Vn, and 24Wn corresponding to the lower-arm switches are disposed in the negative direction side of y axis which is close to the U terminal 14U, the V terminal 14V, and the W terminal 14W.

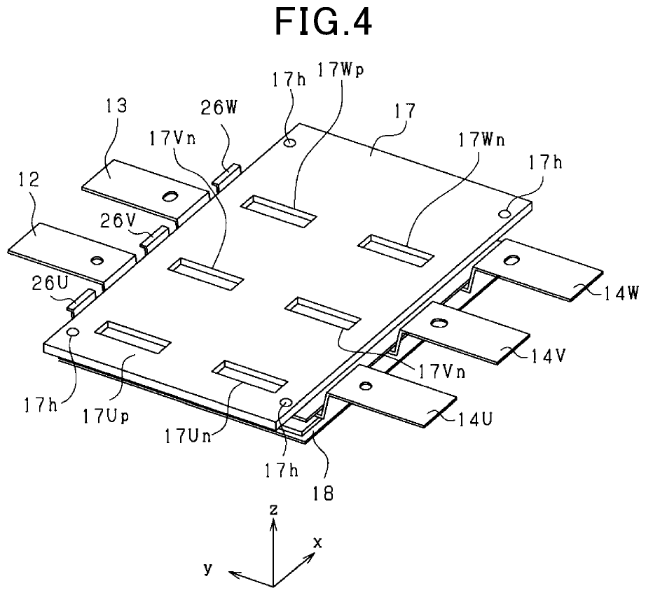

As illustrated in FIGS. 3 and 4, the circuit board 17 includes through holes 17Up, 17Un, 17Vp, 17Vn, 17Wp, and 17Wn which pass through in the z direction and open at positions corresponding to small-signal pads of the semiconductor switching elements 24Up, 24Un, 24Vp, 24Vn, 24Wp, and 24Wn, respectively. A hole portion 17h is provided to each of corners when the top of the circuit board 17 is viewed.

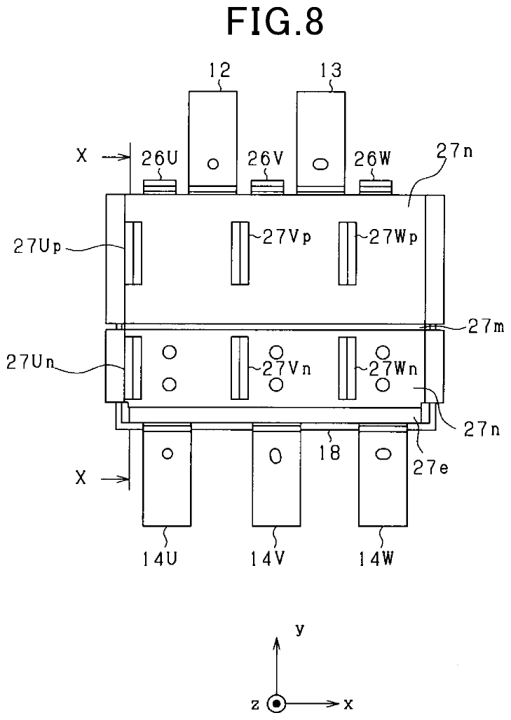

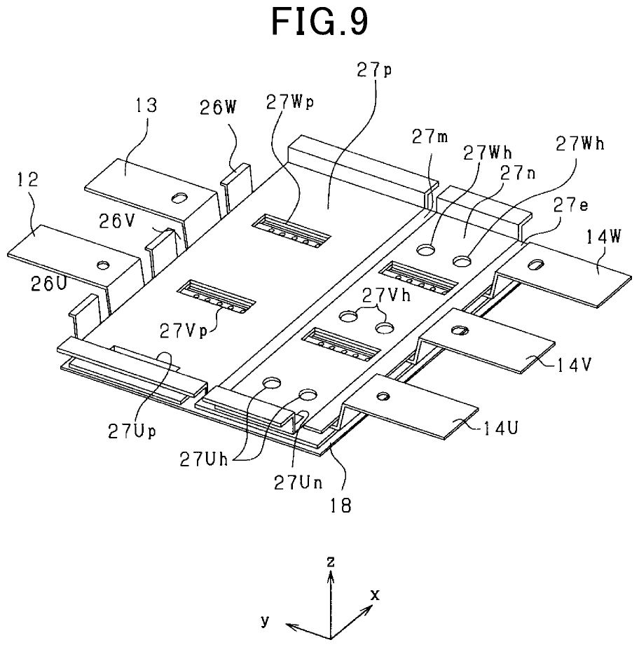

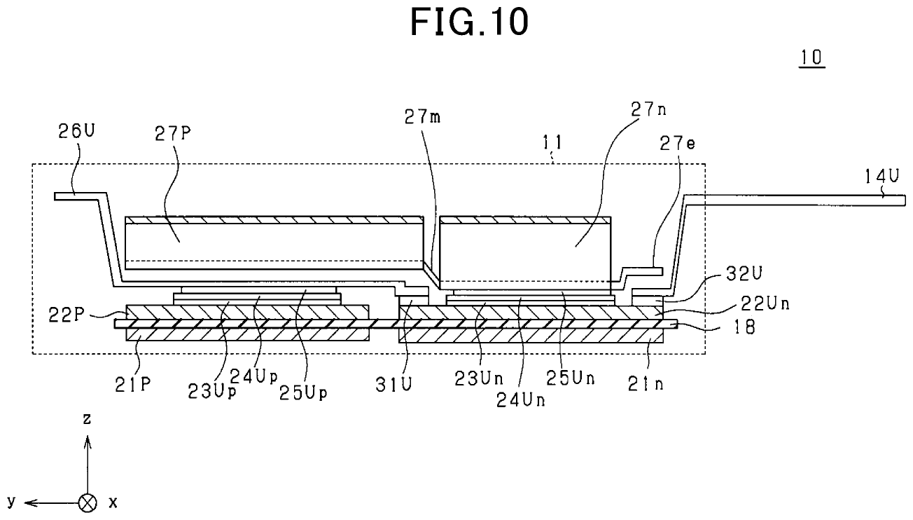

FIGS. 8 to 10 are each a view illustrating a state in which the circuit board 17 is further removed from the semiconductor module 10. A second bus bar 27 is disposed immediately below the circuit board 17. As illustrated in FIG. 8, the second bus bar 27 includes through holes 27Up, 27Un, 27Vp, 27Vn, 27Wp, and 27Wn which pass through in the z direction and open at positions corresponding to small-signal pads of the semiconductor switching elements 24Up, 24Un, 24Vp, 24Vn, 24Wp, and 24Wn.

The through holes 17Up, 17Un, 17Vp, 17Vn, 17Wp, and 17Wn as well as the through holes 27Up, 27Un, 27Vp, 27Vn, 27Wp, and 27Wn are respectively positioned in the upper direction (in the positive direction of z axis) of the small-signal pads of the semiconductor switching elements 24Up, 24Un, 24Vp, 24Vn, 24Wp, and 24Wn, and bonding wires connected to the small-signal pads of the semiconductor switching elements 24Up, 24Un, 24Vp, 24Vn, 24Wp, and 24Wn pass through the corresponding through holes so that the bonding wires can be connected to the upper surface (a surface on the positive direction side of z axis) of the circuit board 17.

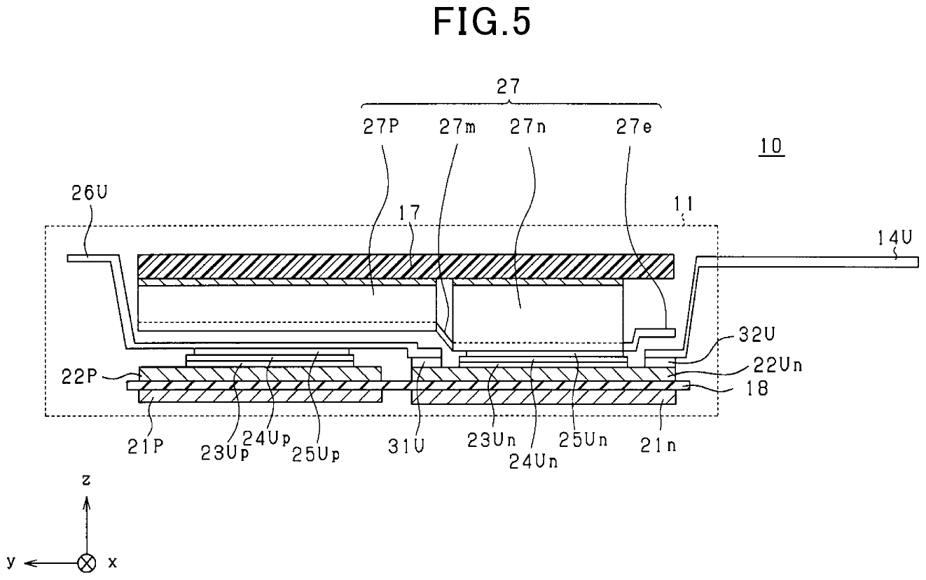

The second bus bar 27 contains, sequentially from the positive direction of y axis, a non-connecting part 27p, a linking part 27m, a connecting part 27n, and an end part 27e. The non-connecting part 27p is positioned upper than the connecting part 27n, and the linking part 27m links the non-connecting part 27p and the connecting part 27n. The end part 27e upwardly rises from the connecting part 27n. As illustrated in FIGS. 5 and 8, the non-connecting part 27p and the connecting part 27n rise in the positive direction of z axis at both ends in the x direction. The second bus bar 27 extends in a region from the upper surface of the semiconductor switching elements 24Un, 24Vn, and 24Wn which corresponds to the lower-arm switches to the N terminal 13 which is adjacent to the P terminal 12. When the circuit board 17 is seen in the plan view direction, the second bus bar 27 covers the plurality of semiconductor switching elements 24Up, 24Un, 24Vp, 24Vn, 24Wp, and 24Wn which are contained in the corresponding legs.

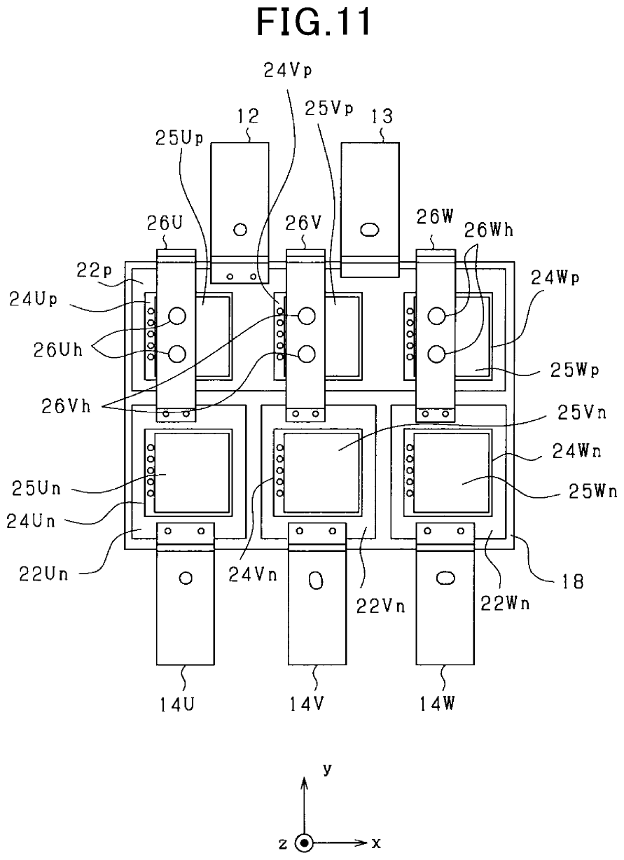

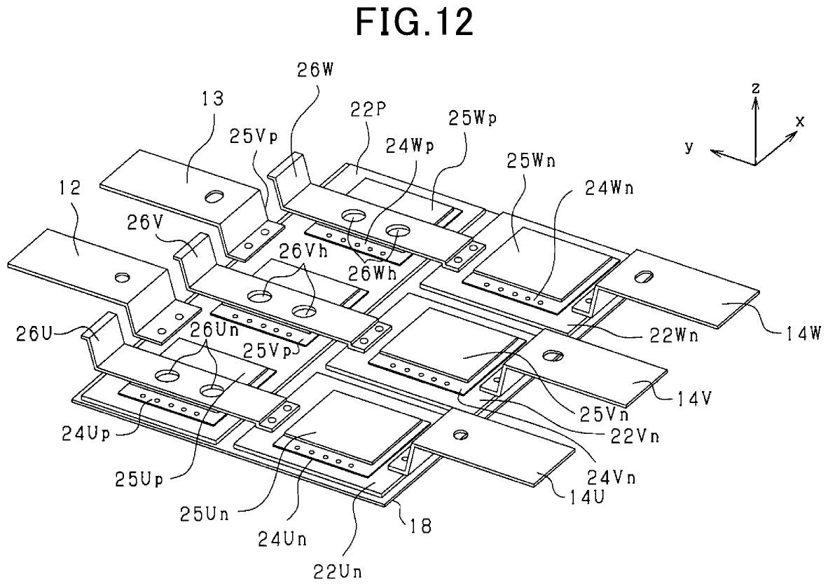

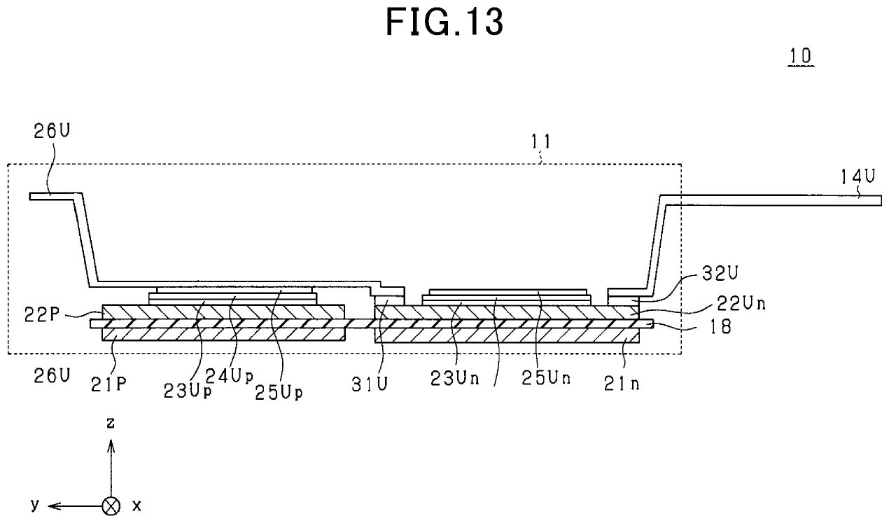

FIGS. 11 to 13 are each a view illustrating a state in which the second bus bar 27 is further removed from the semiconductor module 10. The first bus bars 26U, 26V, and 26W are disposed immediately below the second bus bar 27. When the circuit board 17 is seen in the plan view direction, the first bus bars 26U, 26V, and 26W largely overlap the second bus bar 27. The first bus bars 26U, 26V, and 26W extend in the y axis direction and have a shape of rising in the positive z axis direction at the end in the positive direction of y axis. As illustrated in FIG. 8, portions other than the rising ends of the first bus bars 26U, 26V, and 26W are covered by the second bus bar 27.

As illustrated in FIGS. 5 to 7 or the like, the semiconductor module 10 includes, in the mold 11, first heat dissipation substrates 21p and 21n, an insulating substrate 18, and second heat dissipation substrates 22p, 22Un, 22Vn, and 22Vn, which are laminated sequentially from the lower surface side (the negative direction side of z axis). The first heat dissipation substrates 21p and 21n and the second heat dissipation substrates 22p, 22Un, 22Vn, and 22Vn are each an electrically conductive metal plate and more specifically, for example, a flat plate including copper or the like as a material.

The semiconductor switching elements 24Up, 24Un, 24Vp, 24Vn, 24Wp, and 24Wn are each disposed in such a direction that the p-type collector electrode side is the lower surface side. The semiconductor switching elements 24Up, 24Vp, and 24Wp are bonded to the upper surface of the second heat dissipation substrate 22p via solder layers 23Up, 23Vp, and 23Wp. The semiconductor switching elements 24Un, 24Vn, and 24Wn are bonded to the upper surfaces of the second heat dissipation substrates 22Un, 22Vn, and 22Vn via solder layers 23Un, 23Vn, and 23Wn, respectively. The P terminal 12 is bonded to the end in the positive direction of y axis on the upper surface of the second heat dissipation substrate 22p via a solder layer 33.

The first bus bars 26U, 26V, and 26 W are bonded to the upper surfaces of the semiconductor switching elements 24Up, 24Vp, and 24Wp via solder layers 25Up, 25Vp, and 25Wp, respectively. As illustrated in FIG. 11 or the like, solder hole portions 26Uh, 26Vh, and 26Wh are disposed to the first bus bars 26U, 26V, and 26W, respectively. The solder layers 25Up, 25Vp, and 25Wp can be easily formed by pouring solder from above into the solder hole portions 26Uh, 26Vh, and 26Wh in the state illustrated in FIG. 11, and the first bus bars 26U, 26V, and 26W can be accurately disposed and bonded with respect to the collector electrodes of the semiconductor switching elements 24Up, 24Vp, and 24Wp, respectively. The solder hole portions 26Uh, 26Vh, and 26Wh can also be used for laser welding.

The ends in the negative direction of y axis of the first bus bars 26U, 26V, and 26W are respectively bonded to the upper surfaces of the second heat dissipation substrates 22Un, 22Vn, and 22Vn via a solder layer 31U or the like. The U terminal 14U, the V terminal 14V, and the W terminal 14W are respectively bonded to the upper surfaces of the second heat dissipation substrates 22Un, 22Vn, and 22Vn via a solder layer 32U or the like. To the upper surfaces of the second heat dissipation substrates 22Un, 22Vn, and 22Vn, the first bus bars 26U, 26V, and 26W, the semiconductor switching elements 24Un, 24Vn, and 24Wn, and the U terminal 14U, the V terminal 14V, and the W terminal 14W are respectively bonded sequentially from the positive direction of y axis toward the negative direction.

The first bus bars 26U, 26V, and 26W allow for electrical connection between the upper surfaces as the emitter electrode sides of the semiconductor switching elements 24Up, 24Vp, and 24Wp and the upper surfaces of the second heat dissipation substrates 22Un, 22Vn, and 22Vn which are bonded to the lower surfaces as the collector electrode sides of the semiconductor switching elements 24Un, 24Vn, and 24Wn, respectively. Through the first bus bars 26U, 26V, and 26W, pairs of semiconductor switching elements 24Up and 24Un, 24Vp and 24Vn, and 24Wp and 24Wn contained in the corresponding legs are serially connected to each other, respectively. The first bus bars 26U, 26V, and 26W are each an O bus bar.

As illustrated in FIGS. 5 to 7 or the like, the non-connecting part 27p of the second bus bar 27 is disposed above the connecting portion in the first bus bars 26U, 26V, and 26W with the respective semiconductor switching elements 24Up, 24Vp, and 24Wp. The connecting part 27n of the second bus bar 27 is bonded to the upper surfaces of the semiconductor switching elements 24Un, 24Vn, and 24Wn via respective solder layers 25Un, 25Vn, and 25Wn. The second bus bar 27 is an N bus bar (low potential bus bar) connected to the low potential side of each leg of the inverter circuit illustrated in FIG. 2.

As illustrated in FIG. 8 or the like, solder hole portions 27Uh, 27Vh, and 27Wh are disposed to the connecting part 27n. The solder layers 25Un, 25Vn, and 25Wn can be easily formed by pouring solder from above into the solder hole portions 27Uh, 27Vh, and 27Wh in the state illustrated in FIG. 8, and the second bus bar 27 can be accurately disposed and bonded with respect to the collector electrodes of the semiconductor switching elements 24Un, 24Vn, and 24Wn, respectively. The solder hole portions 27Uh, 27Vh, and 27Wh can also be used for laser welding.

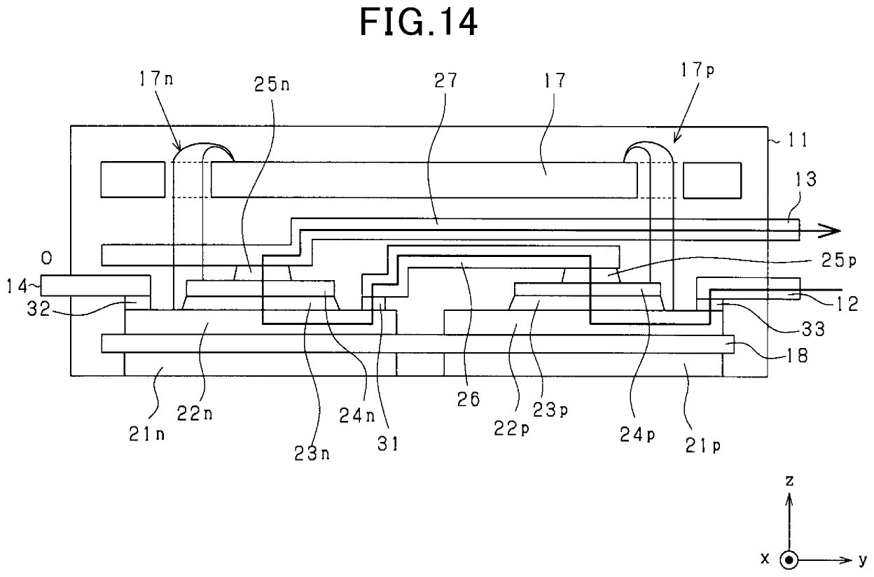

FIG. 14 is a view schematically illustrating a cross section of the semiconductor module 10. Reference numerals in FIG. 14 collectively indicate the same configuration in portions of the reference numerals and numbers in FIGS. 1 to 13. As illustrated in FIG. 14, the semiconductor module 10 is configured that in the mold 11, a semiconductor switching element 24p on the upper arm side and a semiconductor switching element 24n on the lower arm side both constituting the same leg are disposed in the plane direction of the circuit board 17 and serially connected to each other by the first bus bar 26. The collector electrode side of the semiconductor switching element 24p on the upper arm side is electrically connected to the P terminal 12, and the semiconductor switching element 24n on the lower arm side is electrically connected to the N terminal 13 via the second bus bar 27. The second bus bar 27 is disposed between the first bus bar 26 and the circuit board 17 and planarly extends from the semiconductor switching element 24n to the N terminal 13 in such a manner as to cover the lower configuration. For example, when the circuit board 17 is seen in the plan view direction, the first bus bar 26 and the second bus bar 27 largely overlap each other.

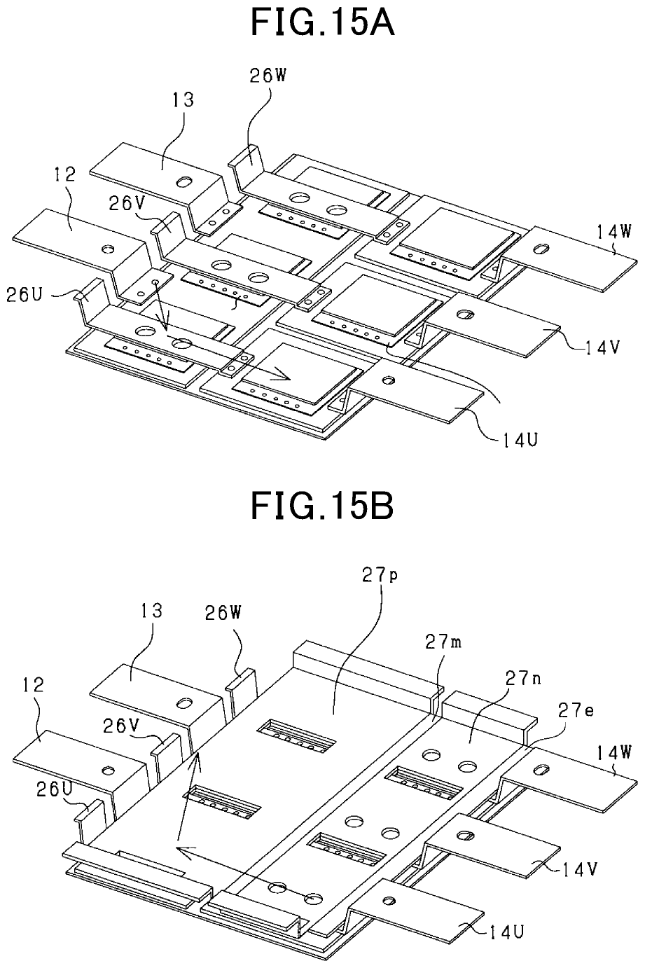

As indicated by the arrow in FIG. 14, when a current flows from the P terminal 12 through a path of the second heat dissipation substrate 22p, the semiconductor switching element 24p, the first bus bar 26, a second heat dissipation plate 22n, the semiconductor switching element 24n, the second bus bar 27, and the N terminal 13, the direction of a current flowing through the first bus bar 26 and the direction of a current flowing through the second bus bar 27 are opposite to each other. More specifically, a current in the negative direction of substantial y axis flows through the first bus bar 26U, as indicated by the arrows in FIG. 14 and FIG. 15A. A current flows through the second bus bar 27 in the positive direction of substantial y axis, as indicated by the arrows in FIG. 14 and FIG. 15B. Since it is configured that the second bus bar 27 is substantially parallel to and spaced apart in the z axis direction from the first bus bar 26 in such a manner as to cover the first bus bar 26, and currents opposite to each other flow, a magnetic field caused by a current flowing through the first bus bar 26 and a magnetic field caused by a current flowing through the second bus bar 27 negate each other. Therefore, a change in a magnetic field attributable to a change in the currents is suppressed at the overlapping location even when a current flowing through the first bus bar 26 and a current flowing through the second bus bar 27 sharply change. As a result, malfunction of the circuit board 17 caused by a change in a current or a potential in the semiconductor module 10 can be suppressed.

Further, in the semiconductor module 10, the second bus bar 27 is disposed between the circuit board 17 and the inverter circuit constituted by the first bus bar 26 and the semiconductor switching elements 24p, 24n, and the like, such that the circuit board 17 and the inverter circuit are isolated from each other by the second bus bar 27. Therefore, the second bus bar 27 serves as an electromagnetic shield, and the magnetic field caused by a change in a current in the circuit board 17 and the magnetic field caused by a change in a current in the inverter circuit can be prevented from influencing each other. As a result, malfunction of the circuit board 17 attributable to a magnetic field occurring in the inverter circuit can be suppressed.

Further, in the semiconductor module 10, the second bus bar 27 is ground-connected. Since the circuit board 17 and the inverter circuit are isolated from each other by the ground-connected second bus bar 27, the second bus bar 27 serves as an electrostatic shield and prevents an electrostatic noise caused by a change in the voltage in the circuit board 17 and an electrostatic noise caused by a change in the voltage in the inverter circuit from influencing each other. In particular, since the second bus bar 27 covers the plurality of semiconductor switching elements 24Up, 24Un, 24Vp, 24Vn, 24Wp, and 24Wn contained in the corresponding legs when the circuit board 17 is seen in the plan view direction, it can more effectively suppress, as an electrostatic shield and an electromagnetic shield, an electrostatic noise and a magnetic noise.

As described above, according to a configuration realized by the semiconductor module 10, a magnetic noise and an electrostatic noise caused by the inverter circuit can be effectively prevented from influencing the circuit board 17. In an inverter circuit including as a semiconductor switching element a power semiconductor element such as an RC-IGBT, a change in a current and a change in a voltage increase, which increases a magnetic noise and an electrostatic noise to a circuit board integrally sealed in a mold. According to the semiconductor module 10, even when an inverter circuit including a power semiconductor element as a semiconductor switching element is sealed together with the circuit board 17 in the mold 11, a magnetic noise and an electrostatic noise caused by the inverter circuit can be effectively suppressed, which can suppress malfunction of the circuit board 17.

### (Modification)

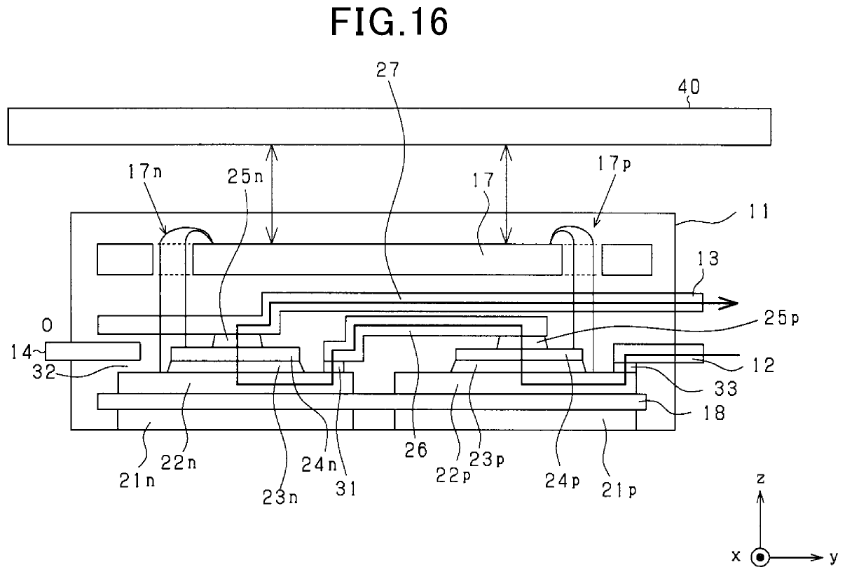

The circuit board 17 may include a wireless communication circuit. With the wireless communication circuit, communications with an external substrate 40 existing outside the semiconductor module 10 are enabled, as illustrated in FIG. 16.

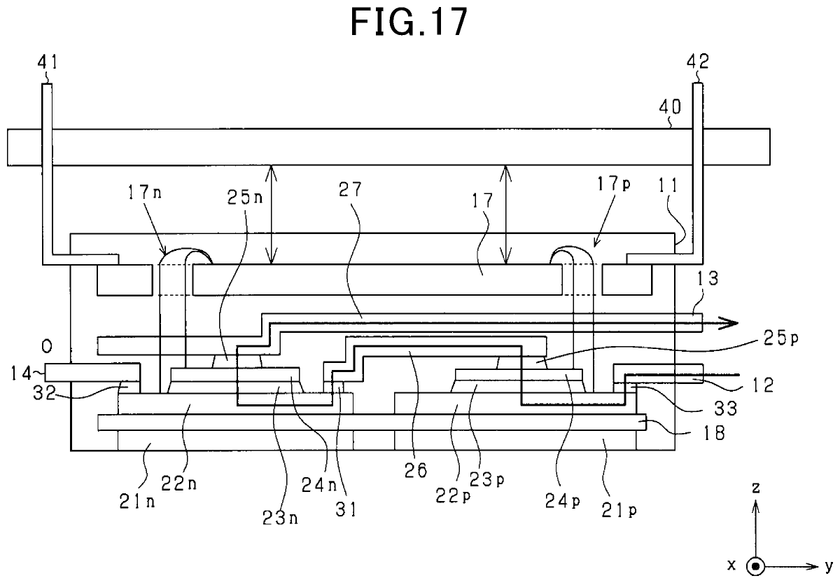

Further, as illustrated in FIG. 17, the semiconductor module 10 may include signal terminals 41 and 42 which are exposed from the mold 11. The signal terminals 41 and 42 are electrically connected to the circuit board 17 and can be connected with the external substrate 40 existing outside the semiconductor module 10 to transmit and receive a signal between the circuit board 17 and the external substrate 40. The signal terminals 41 and 42 preferably project in a direction opposite to a side on which the second bus bar 27 is disposed. It is noted that the signal terminals 41 and 42 may, but not limited to, be directly connected to the circuit board 17 by soldering or the like, as illustrated in FIG. 17. For example, the signal terminals 41 and 42 and the circuit board 17 may be spaced apart from each other in the mold 11 and may be indirectly connected through bonding wires or the like.

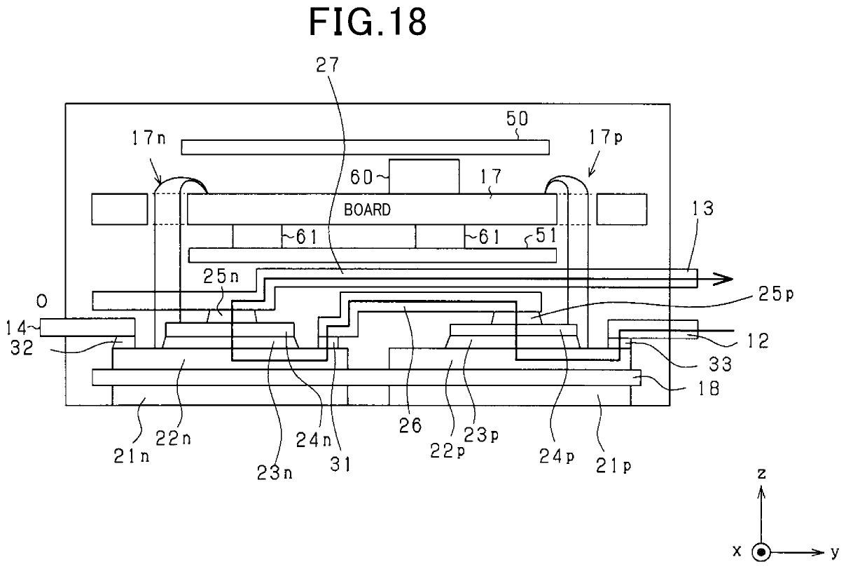

As illustrated in FIG. 18, low shrinkage layers 50 and 51 having a thermal shrinkage lower than that of the mold 11 may be provided in positions away from the circuit board 17 toward the thickness direction of the circuit board 17 in the mold 11. The low shrinkage layers 50 and 51 can prevent the insulating substrate 18 from warping and breaking due to relatively high thermal shrinkages of the resin mold 11, the first heat dissipation substrate 21 made of metal, and the like.

Each of the low shrinkage layers 50 and 51 may be, for example, an air layer. In this case, the low shrinkage layers 50 and 51 can be formed by producing an air layer with a mold during molding. The low shrinkage layer 50 is disposed above a drive IC60 bonded to the upper surface of the circuit board 17, and the low shrinkage layer 51 is disposed below a resistance bonded to the lower surface of the circuit board 17 and above the second bus bar 27. The low shrinkage layers may be disposed either above or below the circuit board 17 or may be disposed both above and below the circuit board 17.

It is noted that the above-described embodiment has been described by illustrating an example in which the plurality of semiconductor switching elements constituting the inverter circuit was an n-channel RC-IGBT, but the present disclosure is not limited thereto. The plurality of semiconductor switching elements may be, for example, power semiconductor elements such as power MOSFETs or IGBTs, and each arm may be configured by antiparallelly connecting a power MOSFET or an IGBT and a diode. Further, the plurality of semiconductor switching elements may be of either n-channel type or p-channel type. Further, the number of semiconductor switching elements constituting the inverter circuit is not limited to six.

The above-described embodiment has been described by illustrating an example in which the second bus bar 27 was an N bus bar connected to the low potential side of each leg, but it may be a P bus bar connected to the high potential side of each leg. A configuration in which the second bus bar 27 serves as a P bus bar can be achieved by exchanging the places of the P terminal 12 and the N terminal 13 and accordingly reversing the connection direction of the semiconductor switching elements.

According to the above-described embodiment, the following effects can be obtained.

The semiconductor module 10 includes the circuit board 17, the plurality of semiconductor switching elements 24Up, 24Un, 24Vp, 24Vn, 24Wp, and 24Wn, the first bus bars 26U, 26V, and 26W, the second bus bar 27, and the mold 11 that integrally seals these configurations. The plurality of semiconductor switching elements 24Up, 24Un, 24Vp, 24Vn, 24Wp, and 24Wn is applied to the inverter circuit connected to the circuit board 17 and disposed in the plane direction of the circuit board 17. The first bus bars 26U, 26V, and 26W serially connect the plurality of semiconductor switching elements (for example, semiconductor switching elements 24Up and 24Un) contained in each leg of the inverter circuit to each other.

The second bus bar 27 is connected to the low potential side of each leg and disposed between the first bus bars 26U, 26V, and 26W and the circuit board 17. The first bus bars 26U, 26V, and 26W and the second bus bar 27 at least partly overlap when the circuit board 17 is seen in the plan view direction, and the direction of a current flowing through the first bus bars 26U, 26V, and 26W is opposite to the direction of a current flowing through the second bus bar 27. Therefore, a change in a magnetic field attributable to a change in a current is suppressed at the overlapping location even when a current flowing through the first bus bars 26U, 26V, and 26W and a current flowing through the second bus bar 27 sharply change. This can suppress the occurrence of a magnetic noise when a current or a potential of each bus bar sharply changes in response to switching of the inverter circuit. In addition, the second bus bar 27 serves as an electromagnetic shield and can prevent the circuit board 17 from being influenced by a magnetic field occurring in response to a change in a current in the inverter circuit. As a result, malfunction of the circuit board 17 caused by a change in a current or a potential in the semiconductor module 10 can be suppressed.

The second bus bar 27 is an N bus bar connected to the low potential side of each leg and ground-connected. Therefore, the second bus bar 27 serves as an electrostatic shield and can suppress malfunction of the circuit board 17 caused by an electrostatic noise occurring in response to a change in a voltage in the circuit board 17.

The circuit board 17 may include a wireless communication circuit for communicating with the outside of the semiconductor module 10. Further, the semiconductor module 10 may include the signal terminals 41 and 42 that are exposed from the mold 11 and electrically connected to the circuit board 17.

When the circuit board 17 is seen in the plan view direction, the second bus bar 27 covers the plurality of semiconductor switching elements 24Up, 24Un, 24Vp, 24Vn, 24Wp, and 24Wn which are contained in the corresponding legs. Therefore, the second bus bar 27 to serve as an electrostatic shield and an electromagnetic shield can more effectively suppress an electrostatic noise and a magnetic noise and can more effectively suppress malfunction of the circuit board 17.

The circuit board 17 may include the through holes 17Up, 17Un, 17Vp, 17Vn, 17Wp, and 17Wn through which bonding wires of the plurality of semiconductor switching elements 24Up, 24Un, 24Vp, 24Vn, 24Wp, and 24Wn are to pass. Similarly, the second bus bar 27 may include the through holes 27Up, 27Un, 27Vp, 27Vn, 27Wp, and 27Wn through which bonding wires of the plurality of semiconductor switching elements 24Up, 24Un, 24Vp, 24Vn, 24Wp, and 24Wn are to pass.

The semiconductor module 10 may include the low shrinkage layers 50 and 51 having a thermal shrinkage lower than that of the mold 11 in positions away from the circuit board 17 toward the thickness direction of the circuit board 17in the mold 11. The low shrinkage layers 50 and 51 can ease thermal shrinkage and suppress breaking of the semiconductor module 10.

The present disclosure has been described in accordance with examples, but it is understood that the present disclosure should not be limited to the examples and configurations. The present disclosure encompasses many variations and modifications within an equivalent range. In addition, various combinations and forms as well as other combinations and forms including one or more/less elements thereto are also within the spirit and scope of the present disclosure.

### (Conclusion)

The present disclosure provides a technology for suppressing the malfunction of the printed circuit board caused by a change in a current or a potential in the semiconductor module.

The present disclosure includes a circuit board, a plurality of semiconductor switching elements applied to an inverter circuit connected to the circuit board, a plurality of bus bars, and a mold that integrally seals the circuit board, the plurality of semiconductor switching elements, and the plurality of bus bars. In this semiconductor module, the plurality of semiconductor switching elements is disposed in a plane direction of the circuit board. The plurality of bus bars includes a first bus bar that serially connects the plurality of semiconductor switching elements contained in each leg of the inverter circuit and a second bus bar that is connected to a high potential side or a low potential side of the leg and disposed between the first bus bar and the circuit board. When the circuit board is seen in the plan view direction, the first bus bar and the second bus bar at least partly overlap each other, and the direction of a current flowing through the first bus bar is opposite to the direction of a current flowing through the second bus bar.

In the semiconductor module according to the present disclosure, the first bus bar and the second bus bar at least partly overlap each other when the circuit board is seen in the plan view direction. Furthermore, since the directions of currents flowing through the first bus bar and the second bus bar are opposite to each other, a change in a magnetic field attributable to a change in the currents is suppressed at the overlapping location even when a current flowing through the first bus bar and a current flowing through the second bus bar sharply change. This can suppress the occurrence of a magnetic noise when a current or a potential of each bus bar sharply changes in response to switching of the inverter circuit. In addition, the second bus bar serves as an electromagnetic shield and can prevent the circuit board from being influenced by the magnetic field caused by a change in a current in the inverter circuit. As a result, malfunction of the circuit board caused by a change in a current or a potential in the semiconductor module can be suppressed.

What is claimed is:

1. A semiconductor module comprising a circuit board, a plurality of semiconductor switching elements applied to an inverter circuit connected to the circuit board, a plurality of bus bars, and a mold that integrally seals the circuit board, the plurality of semiconductor switching elements, and the plurality of bus bars, wherein
the plurality of semiconductor switching elements is disposed in a plane direction of the circuit board,
the plurality of bus bars includes:
a first bus bar that serially connects the plurality of semiconductor switching elements contained in each leg of the inverter circuit to each other, and
a second bus bar that is connected to a high potential side or a low potential side of the leg and disposed between the first bus bar and the circuit board,
the first bus bar and the second bus bar at least partly overlap when the circuit board is seen in a plan view direction,
a direction of a current flowing through the first bus bar is opposite to a direction of a current flowing through the second bus bar, and
the circuit board includes through holes through which bonding wires of the plurality of semiconductor switching elements are to pass.

2. The semiconductor module according to claim 1, wherein the second bus bar covers the plurality of semiconductor switching elements contained in the leg when the circuit board is seen in a plan view direction.

3. A semiconductor module comprising a circuit board, a plurality of semiconductor switching elements applied to an inverter circuit connected to the circuit board, a plurality of bus bars, and a mold that integrally seals the circuit board, the plurality of semiconductor switching elements, and the plurality of bus bars, wherein
the plurality of semiconductor switching elements is disposed in a plane direction of the circuit board,
the plurality of bus bars includes:
a first bus bar that serially connects the plurality of semiconductor switching elements contained in each leg of the inverter circuit to each other, and
a second bus bar that is connected to a high potential side or a low potential side of the leg and disposed between the first bus bar and the circuit board,
the first bus bar and the second bus bar at least partly overlap when the circuit board is seen in a plan view direction,
a direction of a current flowing through the first bus bar is opposite to a direction of a current flowing through the second bus bar, and
the second bus bar covers the plurality of semiconductor switching elements contained in the leg when the circuit board is seen in a plan view direction.

4. The semiconductor module according to claim 1, wherein the second bus bar is a low potential bus bar connected to a low potential side of the leg and ground-connected.

5. The semiconductor module according to claim 1, wherein the circuit board includes a wireless communication circuit for communicating with an outside of the semiconductor module.

6. The semiconductor module according to claim 1, comprising a signal terminal that is exposed from the mold and electrically connected to the circuit board.

7. The semiconductor module according to claim 1, comprising a low shrinkage layer having a thermal shrinkage lower than a thermal shrinkage of the mold in a position away from the circuit board toward a thickness direction of the circuit board in the mold.
